(19) United States
(12) Patent Application Publication
(10) Pub. No.: US 2008/0150584 A1
(43) Pub. Date: Jun. 26, 2008

(54) CML CIRCUIT

(75) Inventor: Makoto TANAKA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/936,276

(22) Filed: Nov. 7, 2007

(30) Foreign Application Priority Data
Dec. 21, 2006 (JP) 2006-344656

(51) Int. Cl. H03K 19/094; H03K 19/20

(52) U.S. Cl. 326/83; 326/115

(57) ABSTRACT

Disclosed herein is a CML circuit that can solve a conventional problem that it has been impossible to input a large amplitude signal to a differential pair. The CML circuit of the present invention includes an internal signal generation circuit for generating an input differential signal having an amplitude to be ranged approximately from a ground potential to a power supply potential, a first MOS transistor having a gate for inputting a differential signal having one of the two amplitudes, a second MOS transistor having a gate for inputting a differential signal having the other of the two amplitudes and having a common source shared with the first MOS transistor, a first resistance element connected between the drain of the first MOS transistor and a first power supply terminal, a second resistance element connected between the drain of the second MOS transistor and the first power supply terminal, a third MOS transistor connected to the first resistance element in parallel, and a fourth MOS transistor connected to the second resistance element in parallel.

### BACKGROUND OF THE INVENTION

1. Field of the Invention

The present invention relates to a CML circuit, more particularly to a CML circuit corresponding to an input signal having an amplitude to be ranged approximately from a ground potential to a power supply potential.

2. Description of Related Art

In recent years, data communication speed in or between semiconductor devices has remarkably been improved. In order to cope with such fast data communications, amplitudes of signals to be sent and received are reduced to improve the signal frequencies. And now differential signals with high noise resistance are used for such fast data communications.

An ECL (Emitter Coupled Logic) circuit and a CML (Current Mode Logic) circuit have been proposed to handle those differential signals having a small amplitude respectively. FIG. 2 shows an example of a general CML circuit 100 (conventional example 1). As shown in FIG. 2, the CML circuit 100 includes PMOS transistors M11 and M12 that forms a differential pair and resistors R11 and R12 that are connected between the drains of the PMOS transistors M11 and M12 and aground terminal respectively. The CML circuit also includes a current source transistor M13 for operating the differential pair.

The PMOS transistors M11 and M12 input differential signals having amplitudes to be ranged from a ground potential to a power supply potential from the CMOS circuits 111 and 112 respectively. At this time, each of the PMOS transistors M11 and M12 enables a current to flow to the corresponding one of the resistors R11 and R12 in accordance with the voltage level of the input signal and outputs a signal having an amplitude in accordance with the resistance value of the corresponding one of the resistors R11 and R12 and the current flowing in the resistor from its output terminal OUT1/OUT2.

However, the CML 100 is required to reduce the resistance values of the resistors R11 and R12 to increase the constant current that flows in the PMOS transistors M11 and M12 respectively to make a rise of the output signals faster. This is why the CML circuit 100 causes a problem that the power consumption rises when generating high frequency differential signals.

On the other hand, JP 2 (1990)-295314 A (conventional example 2) discloses an example of the ECL circuit. FIG. 3 shows a circuit diagram of the ECL circuit 200 in the conventional example 2. As shown in FIG. 3, the ECL circuit 200 includes NPN transistors Q1 and Q2 that forms a differential pair and resistors R21 and R22 that are connected between the collectors of the NPN transistors Q1 and Q2 and a power supply terminal respectively. Furthermore, the resistors R21 and R22 are connected to PMOS transistors M21 and M22 in parallel respectively. The ECL circuit 200 also includes a current source for operating the differential pair.

A differential signal is inputted to the base of each of the NPN transistors Q1 and Q2 and to the gate of each of the PMOS transistors M21 and M22. At this time, each of the NPN transistors Q1 and Q2 flows a current to its corresponding resistor R21/R22 in accordance with the input signal level and outputs a signal having an amplitude according to the current flown in the resistor R21/R22 from the output terminal OUT1/OUT2. Each of the PMOS transistors M21 and M22 functions to shorten the rising time of a signal output from the output terminal OUT1/OUT2.

However, the ECL circuit 200 has a problem that it is impossible to input a signal having an amplitude large enough to enable switching between PMOS transistors M21 and M22 to the base of each NPN transistor. This is because the base-emitter voltage Vbe of the NPN transistor comes to limit the amplitude of the input signal. If the base of the NPN transistor inputs a signal having a large amplitude, the NPN transistor is saturated and this disturbs fast operation of the ECL circuit.

Next, there will be described the operation of a bipolar transistor to solve this problem. A bipolar transistor flows a collector current Ic in accordance with a size of the base current Ib when the base-emitter voltage Vbe is over the diode voltage (0.7 V or so generally). This diode voltage is caused by a diode formed between the base and the emitter of the bipolar transistor and it is a threshold voltage of the bipolar transistor. And because the base-emitter voltage Vbe is caused by the diode characteristics, if the base-emitter voltage Vbe changes, the current flowing from the base to the emitter (transistor base current Ib) also changes exponentially. In other words, the base-emitter voltage Vbe hardly changes even upon a significant change of the base current Ib. Consequently, the base voltage is clamped at the base-emitter voltage Vbe, thereby being prevented from significant changes. This is why the base of the NPN transistor of the ECL circuit 200 cannot input any signals having a large amplitude.

If the base of the ECL circuit 200 inputs a large amplitude signal, the NPN transistors Q1 and Q2 are saturated in a conductive state. A bipolar transistor increases the collector current Ic when the input signal level rises in such a conductive state. And when the collector current Ic increases, the collector voltage Vc determined by the collector current Ic and the resistor connected to the collector falls, thereby the collector voltage Vc of the NPN transistor falls under the base voltage Vb. “Saturation” means a state in which the emitter-collector voltage Vce in such a state falls to the lower limit value (e.g., 0.2 V or so) of the emitter-collector voltage Vce. And in such a saturation state, the depleted layer of the phase boundary between the collector N-type semiconductor and the base P-type semiconductor is reduced in size. In order to turn off a transistor in such a saturation state, it is required to restore the original size of the depleted layer and set it in the non-saturated on-state, then to the off-state. Consequently, if an input signal is given to a transistor so as to saturate the transistor, much time is required to switch the transistor between the on-state and the off-state. This means that the transistor is prevented from fast operation.

### SUMMARY

The CML circuit 100 in the conventional example 1 has a problem that it is difficult to obtain a high frequency output signal at low power consumption. On the other hand, the CML circuit 200 in the conventional example 2 has a problem that the CML circuit 200 cannot operate according to an input signal having a large amplitude to be ranged from a ground potential to a power supply potential.

The CML circuit of the present invention includes an internal signal generation circuit for generating an input differential signal having an amplitude to be ranged approximately from a ground potential to a power supply potential; a first MOS transistor for inputting a differential signal having one of the two amplitudes to its gate; a second MOS transistor for inputting a differential signal having the other of the two amplitudes and having a source shared with the first MOS transistor; a first resistance element connected between a drain of the first MOS transistor and a first power supply terminal; a second resistance element connected between a drain of the second MOS transistor and the first power supply terminal; a third MOS transistor connected to the first resistance element in parallel; and a fourth MOS transistor connected to the second resistance element in parallel.

In other aspect, a semiconductor circuit has a node, a first pair of terminals inputting differential signals, a second pair of terminals outputting differential signals, a first resistance element having a first electrode coupled to a first terminal of the second pair of terminals and a second electrode coupled to a first voltage, a second resistance element having a first electrode coupled to a second terminal of the second pair of terminals and a second electrode coupled to the first voltage, a current supply coupled to the node to source a current, and a second voltage, a first CMOS gate coupled to the node to sink the current and a first terminal of the first pair of terminals, and the first terminal of the second pair of terminals, and a second CMOS gate coupled to the node to sink the current and a second terminal of the first pair of terminals, and the second terminal of the second pair of terminals.

The CML circuit of the present invention forms a differential pair with the first and second MOS transistors, thereby inputting a differential signal generated by an internal signal generation circuit and having an amplitude to be ranged approximately from a ground potential to a power supply potential without changing the signal amplitude. In addition, the employment of the third and fourth MOS transistors makes it possible to shorten the time of rising or falling of each signal generated by the first and second resistance elements without increasing the current supplied from the differential pair to the first and second resistance elements.

The CML circuit of the present invention can realize fast operations without changing the signal level of the input differential signal having an amplitude to be ranged approximately from a ground potential to a power supply potential.

### BRIEF DESCRIPTION OF THE DRAWINGS

FIG. 1 is a circuit diagram of a CML circuit in the first embodiment;

FIG. 2 is a circuit diagram of a CML circuit in the conventional example 1; and

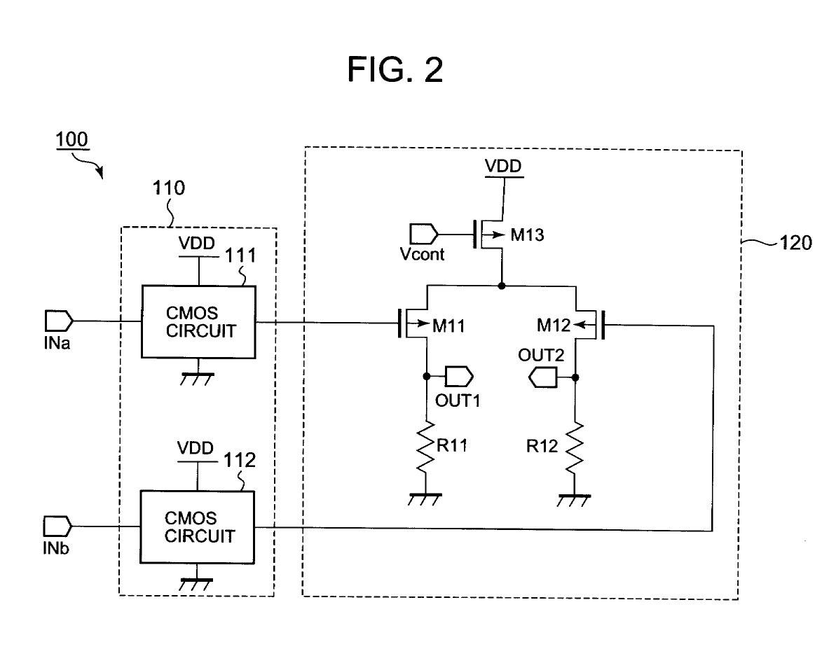

FIG. 3 is a circuit diagram of an ECL circuit in the conventional example 2.

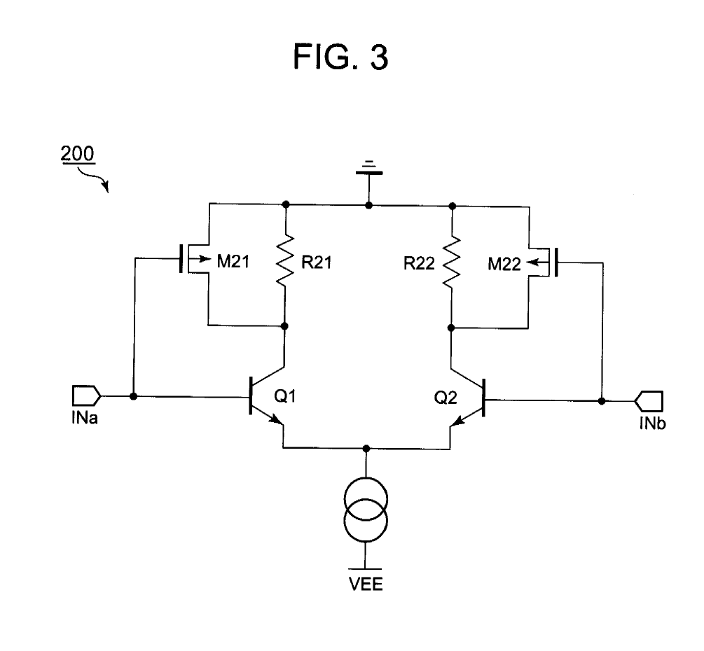

### DETAILED DESCRIPTION OF THE PREFERRED EMBODIMENTS

### First Embodiment

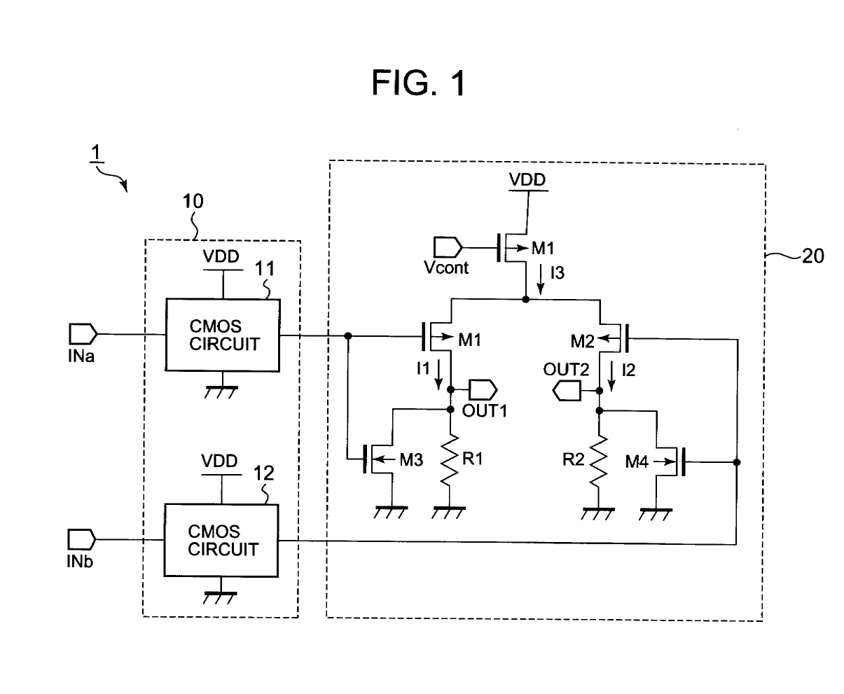

Hereunder, there will be described an embodiment of the present invention with reference to the accompanying drawings. FIG. 1 shows a circuit diagram of a CML circuit 1 in this first embodiment. The CML circuit 1 is driven according to a ground potential GND supplied from a first power supply terminal (e.g., a ground terminal) and a power supply potential VDD supplied from a second power supply terminal (e.g., a power supply terminal).

As shown in FIG. 1, the CML circuit 1 includes an internal signal generation circuit 10 and an amplification circuit 20. The internal signal generation circuit 10 includes CMOS circuits 11 and 12. Each of the CMOS circuits 11 and 12 is driven according to the power supply potential VDD and the ground potential GND and outputs a signal having an amplitude to be ranged approximately from a ground potential to a power supply potential according to a signal inputted from corresponding one of the input terminals INa and INb. The output signal of the CMOS circuit 11 and the output signal of the CMOS circuit 12 are differential signals that are inverted in phase from each other in this embodiment.

The amplification circuit 20 includes first to fourth MOS transistors and first and second resistance elements. In this embodiment, a PMOS transistor M1 is used as the first MOS transistor, a PMOS transistor M2 is used as the second MOS transistor, an NMOS transistor M3 is used as the third MOS transistor, and an NMOS transistor is used as the fourth MOS transistor. And a resistor R1 is used as the first resistance element and a resistor R2 is used as the second resistance element. In this embodiment, the PMOS transistor M1 is used as a power source for setting an operation current of the amplification circuit 20. A PMOS transistor forms its source and drain with P-type semiconductors and an NMOS transistor forms its source and drain with N-type semiconductors.

The PMOS transistors M1 and M2 are driven as a differential pair having a commonly connected source. And a PMOS transistor M1 is connected between the power supply terminal and the common node (source) of the PMOS transistors M1 and M2. And a control terminal Vcont is connected to the gate of the PMOS transistor M1. This control terminal Vcont applies a voltage to the gate of the PMOS transistor M1. The voltage is used to set a current level of a current 13 that flows into the PMOS transistor M1.

The resistor R1 is connected between the ground terminal and the drain of the PMOS transistor M1. The NMOS transistor M3 is connected to the resistance R1 in parallel. The gate of the PMOS transistor M1 inputs a differential signal having one of the amplitudes from the CMOS circuit 11. The gate of the PMOS transistor M3 inputs the same signal as that inputted to the gate of the PMOS transistor M1. In this embodiment, a common gate is connected to the PMOS transistors M1 and M3. This common node inputs a signal having one of the amplitudes output from the CMOS circuit 11, thereby the same signal is inputted to the gates of the two MOS transistors. The first output terminal OUT1 is connected between the resistor R1 and the drain of the PMOS transistor M1.

On the other hand, the resistor R2 is connected between the ground terminal and the drain of the PMOS transistor M2. The NMOS transistor M4 is connected to the resistance R2 in parallel. The gate of the PMOS transistor M2 inputs a differential signal having the other amplitude from the CMOS circuit 12. The gate of the PMOS transistor M4 inputs the same signal as that inputted to the gate of the PMOS transistor M2. In this embodiment, a common gate is connected to the PMOS transistors M2 and M4. This common node inputs a signal having the other amplitude and output from the CMOS circuit 12, thereby the same signal is inputted to the gates of the two MOS transistors. The second output terminal OUT2 is connected to a node between the resistor R2 and the drain of the PMOS transistor M2.

Next, there will be described the operation of the CML circuit 1 in this embodiment. At first, there will be described an operation of the CML circuit 1 when the CMOS circuit 11 outputs a high level signal (e.g., a power supply potential VDD) and the CMOS circuit 12 outputs a low level signal (e.g., a ground potential GND). In this case, the PMOS transistor M1 is turned off. Consequently, the PMOS transistor M1 shuts off the current I1, thereby the voltage V1L generated at both sides of the resistor R1 becomes 0 V substantially. And according to the level change of the signal output from the CMOS circuit 11 from high to low, the NMOS transistor M3 is turned on, there by the signal level of the first output terminal OUT1 falls sharply to the ground potential GND.

On the other hand, the PMOS transistor M2 is turned on at this time. Consequently, PMOS transistor M2 enables a current I2 to flow according to an amount of a current I3 to generate a voltage V2H at both sides of the resistor R2 according to the value of the current I2 and the value of the resistor R2. Consequently, the second output terminal OUT2 outputs a voltage V2H generated by the resistor R2. And according to the level change of the signal output from the CMOS circuit 12 from high to low, the NMOS transistor M4 is turned off and practically disabled.

Next, there will be described the operation of the CML circuit 200 when the CMOS circuit 11 outputs a low level signal and the CMOS circuit 12 outputs a high level signal. In this case, the PMOS transistor M1 is turned on at this time. Consequently, PMOS transistor M1 enables a current I1 to flow according to an amount of a current I3 to generate a voltage V1H at both sides of the resistor R1 in accordance with the value of the current I1 and the value of the resistor R1. Consequently, the first output terminal OUT1 outputs a voltage V1H generated by the resistor R1. And according to the level change of the signal output from the CMOS circuit 11 from high to low, the NMOS transistor M3 is turned off and practically disabled.

On the other hand, the PMOS transistor M2 is turned off. Consequently, the PMOS transistor M2 shuts off the current I2, thereby the voltage V2L generated at both sides of the resistor R2 becomes 0 V substantially. And according to the level change of the signal output from the CMOS circuit 12 from low to high, the NMOS transistor M4 is turned on, thereby the signal level of the first output terminal OUT2 falls sharply to the ground potential GND.

This means that the CML circuit 1 in this embodiment generates a differential signal that varies the signal level according to the change of the input differential signal. At this time, the same value is assumed for the resistors R1 and R2 while the same amplitude can be set for both the output differential signals. It is also possible to set the current value and the resistance value lower than the power supply potential VDD.

As described above, because the CML circuit in this embodiment uses PMOS transistors M1 and M2 to form a differential pair, the input differential signal is not limited in amplitude, although it is limited in the conventional example 2 in which the differential pair is formed with bipolar transistors. In other words, it is possible to input the same input differential signals as those to the PMOS transistors M1 and M2 to the gates of the NMOS transistors M3 and M4 used to speedup the falling time of each output differential signal. In addition, because the same signal is inputted to the PMOS transistors M1 and M2, as well as to the NMOS transistors M3 and M4, those transistors can be synchronized accurately with other transistors to which the same signal is inputted, thereby improving the accuracy of the output differential signals.

The ECL circuit 200 in the conventional example 1, when inputting a differential signal to the differential pair configured by bipolar transistors, requires a level change circuit to reduce the amplitude of a signal having an amplitude to be ranged from the ground potential GND to the power supply potential VDD. However, the CML circuit 1 in this embodiment can input such a signal having an amplitude to be ranged between the ground potential GND and the power supply potential VDD without using a level change circuit, etc. This means that the CML circuit 1 in this embodiment can reduce the circuit size more than the ECL circuit 200 in the conventional example 2. And because the circuit scale is such small, the total power consumption of the CML circuit 1 is also reduced.

Furthermore, in the CML circuit shown in the conventional example 1, it is required to reduce the resistance values of the first and second resistance elements and supply a large current to the differential pair so as to speed up the rising and falling times of each output differential signal. In the CML circuit in this embodiment, however, the NMOS transistors M3 and M4 can reduce the falling time of each output signal, so that there is no need to increase the supply current to the differential pair specially. This means that the CML circuit in this embodiment can generate a high frequency output differential signal at lower power consumption than the CML circuit in the conventional example 1.

The present invention is not limited only to the above embodiment; it is to be understood that modifications will be apparent to those skilled in the art without departing from the spirit of the invention. For example, the ground potential GND and the power supply potential VDD may be replaced with each other in the amplification circuit 20 shown in FIG. 1 to change the PMOS transistor to the NMOS transistor and the NMOS transistor to the PMOS transistor respectively, thereby forming the differential pair with NMOS transistors.

What is claimed is:

1. A semiconductor circuit, comprising:
a node;
a first pair of terminals to receive input differential signals;
a second pair of terminals to reveal output differential signals;
a first resistance element having one end thereof coupled to a first terminal of the second pair of terminals and another and thereof coupled to receive a first voltage;
a second resistance element having one end thereof coupled to a second terminal of the second pair of terminals and another end thereof coupled to receive the first voltage;
a current supply coupled to the node to flow a current;
a first CMOS gate coupled to the node, a first terminal of the first pair of terminals, and the first terminal of the second pair of terminals; and
a second CMOS gate coupled to the node, a second terminal of the first pair of terminals, and the second terminals of the second pair of terminals.

2. The semiconductor circuit according to claim 1, further comprising:
a signal generator coupled to the first pair of terminals to input the differential signals.

3. The semiconductor circuit according to claim 2,
wherein said current supply is supplied with a second voltage, and
wherein the signal generator comprises a plurality of CMOS gates coupled to the first voltage and the second voltage.

4. A combination, comprising:
a node;
a first pair of terminals outputting differential signals;
an internal signal generation circuit having a second pair of terminals to output internal differential signals;
a first MOS transistor having a control electrode coupled to a first terminal of the second pair of terminals, a first current conducting electrode coupled to a first terminal of the first pair of terminals, and a second current conducting electrode coupled to the node;
a second MOS transistor having a control electrode coupled to a second terminal of the second pair of terminals, a first current conducting electrode coupled to a second terminal of the first pair of terminals, and a second current conducting electrode coupled to the node;
a first resistance element having a first electrode coupled to the first terminal of the first pair of terminals and a second electrode coupled to a first voltage;
a second resistance element having a first electrode coupled to the second terminal of the first pair of terminals and a second electrode coupled to a first voltage;
a current supply coupled to the node to source a current;
a third MOS transistor having a control electrode coupled to the first terminal of the second pair of terminals, a first current conducting electrode coupled to the first terminal of the first pair of terminals, and a second current conducting electrode coupled to the first voltage; and
a fourth MOS transistor having a control electrode coupled to the second terminal of the second pair of terminals, a first current conducting electrode coupled to the second terminal of the first pair of terminals, and a second current conducting electrode coupled to the first voltage.

5. The CML circuit according to claim 4,
wherein the first and second MOS transistors differ in conduction type from the third and fourth MOS transistors.

6. The semiconductor circuit according to claim 5,
wherein said current supply is supplied with a second voltage, and
wherein the signal generator comprises a plurality of CMOS gates coupled to the first voltage and the second voltage.
